(19) United States
(12) Patent Application Publication
(10) Pub. No.: US 2012/0153378 A1
(43) Pub. Date: Jun. 21, 2012

(54) SEMICONDUCTOR DEVICE AND METHOD FOR FORMING THE SAME

(75) Inventor: Jung Nam KIM, Seoul (KR)

(73) Assignee: Hynix Semiconductor Inc., Icheon (KR)

(21) Appl. No.: 13/018,743

(22) Filed: Feb. 1, 2011

(30) Foreign Application Priority Data
Dec. 15, 2010 (KR) 10-2010-0128576

(51) Int. Cl. H01L 29/78; H01L 21/336

(52) U.S. Cl. 257/329; 438/269; 257/E29.262; 257/E21.41

(57) ABSTRACT

A semiconductor device and a method for forming the same are disclosed. The semiconductor device prevents separation between the channel region and the semiconductor substrate to prevent the floating body effect and to guarantee a sufficient overlap between a gate and a junction region. The semiconductor device includes a vertical pillar including a vertical channel, a diffusion control layer contained in the vertical pillar, and a junction region formed close to the diffusion control layer in the vertical pillar.

### CROSS-REFERENCE TO RELATED APPLICATION

The priority of Korean patent application No. 10-2010-0128576 filed on 15 Dec. 2010, the disclosure of which is hereby incorporated in its entirety by reference, is claimed.

### BACKGROUND OF THE INVENTION

Embodiments of the present invention relate to a semiconductor device and a method for forming the same, and more particularly, to a semiconductor device that has a vertical channel and a method for forming the same.

Generally, a semiconductor is a material that could be made conductive by providing dopants into the material. Although a semiconductor is similar to a nonconductor in a pure state, the electric conductivity of a semiconductor device is increased by impurity implantation or other manipulation. The semiconductor is used to form a semiconductor device, such as a transistor, through impurity implantation and a wire interconnection. A device that has various functions simultaneously while being formed of a semiconductor element is referred to as a semiconductor device. A representative example of the semiconductor device is a semiconductor memory device.

A semiconductor memory device includes a plurality of unit cells, each of which includes a capacitor and a transistor. The capacitor is used to temporarily store data. The transistor is used to transmit data between a bit line and a capacitor in correspondence with a control signal (i.e., a word line) using the electric conductivity of a semiconductor device that changes depending on environment. The transistor has three regions including a gate, a source, and a drain, where charges between the source and the drain move in response to a control signal input to the gate. The charges between the source and the drain move through a channel region in accordance with the properties and operation of the semiconductor device.

When a general transistor is formed in a semiconductor substrate, a gate is formed in the semiconductor substrate, and impurities are doped at both sides of the gate to form a source and a drain. In this case, a region between a source and a drain under the gate becomes a channel region of the transistor. The transistor, including a horizontal channel region, occupies the semiconductor substrate having a predetermined area. Reducing the overall area of a complicated semiconductor memory apparatus is difficult due to the plurality of transistors contained in the semiconductor device.

If the overall area of the semiconductor memory device is reduced, the number of semiconductor memory devices formed in a given wafer size is increased to increase productivity. A variety of methods have been proposed to reduce the unit cell size of the semiconductor memory device. A representative method is a three dimensional (3D) transistor, including a vertical transistor that has a vertical channel region, instead of a conventional planar transistor that has a planar channel region.

### BRIEF SUMMARY OF THE INVENTION

Various embodiments of the present invention are directed to providing a semiconductor device and a method for forming the same that substantially obviate one or more problems due to limitations and disadvantages of the conventional art.

An embodiment of the present invention relates to a semiconductor device and a method for forming the same, which form a diffusion control layer at the center of a vertical pillar so as to prevent a channel region and a semiconductor substrate from being isolated from each other, thereby preventing a floating body effect. In addition, the semiconductor device and the method for forming the same according to the embodiment of the present invention can guarantee a sufficient-sized overlapping region between a gate and a junction region.

In accordance with an aspect of the present invention, a semiconductor device includes a vertical pillar including a vertical channel; a diffusion control layer contained in the vertical pillar; and a junction region formed close to the diffusion control layer in the vertical pillar. The semiconductor device prevents the isolation between a channel region and a semiconductor substrate so as to prevent the floating body effect, and guarantees a sufficient-sized overlapping region between a gate and a junction region.

The diffusion control layer may include an oxide film or a nitride film. The diffusion control layer may be formed of a material capable of preventing ion diffusion.

The diffusion control layer may be configured in a form of a square plate. A height of an upper end of the diffusion control layer is identical or higher than that of a lower end of the vertical channel. Preferably, ion implantation or ion diffusion through the diffusion control layer may be prevented in the vertical pillar.

A distance (a) between the diffusion control layer and a sidewall of one side of the vertical pillar may be set to 0.5 to 2 times a distance (b) between the diffusion control layer and a sidewall of another side of the vertical pillar, such that the diffusion prevention effect can be maximized.

When forming the vertical channel, the semiconductor device may further include a junction region formed over the vertical channel in the vertical pillar.

The semiconductor device may further include a bit line formed at a lateral surface of a lower part of the vertical pillar. The junction region may be located between a sidewall of the bit line of the vertical pillar and the diffusion control layer.

The diffusion control layer may be formed parallel to the bit line, and may be extended from a sidewall of one side of the vertical pillar to a sidewall of another side of the vertical pillar, such that ion diffusion can be prevented.

The semiconductor device may further include a sidewall contact formed at one sidewall of the vertical pillar so as to electrically couple the junction region to the bit line. Preferably, ion implantation or ion diffusion may be carried out through the sidewall contact.

The semiconductor device may further include a word line extended in a direction perpendicular to the bit line at a lateral surface of the vertical channel of the vertical pillar.

In accordance with another aspect of the present invention, a method for forming a semiconductor device includes forming a diffusion control layer over a semiconductor substrate; forming a vertical pillar including a vertical channel in a vicinity of the diffusion control layer; and forming a junction region to be close to the diffusion control layer in the vertical pillar. The method for forming the semiconductor device prevents isolation between a channel region and a semiconductor substrate to prevent the floating body effect, and guarantees a sufficient-sized overlapping region between a gate and a junction region.

The forming of the diffusion control layer may include forming a trench by etching the semiconductor substrate, and forming an insulation film at both sidewalls of the trench. The insulation film includes an oxide film or a nitride film.

The forming of the vertical pillar may include forming a silicon layer over the semiconductor substrate over which the diffusion control layer is formed; burying the insulation film; and etching the silicon layer in a pillar form. Preferably, the diffusion control layer may be buried in the pillar.

The forming of the silicon layer may include performing a selective epitaxial growth (SEG) on the semiconductor substrate over which the diffusion control layer is formed, and planarizing an upper part of the SEG-processed silicon layer.

The forming of the junction region may include forming a sidewall contact at a sidewall of one side of the vertical pillar, and performing ion implantation or ion diffusion through the sidewall contact. In this case, a distance (a) between the diffusion control layer and a sidewall of one side of the vertical pillar may be set to 0.5 to 2 times a distance (b) between the diffusion control layer and a sidewall of another side of the vertical pillar.

The method may further include, after forming a junction region close to the diffusion control layer, forming a junction region over the vertical channel in the vertical pillar.

The method may further include, after forming a junction region close to the diffusion control layer, forming a bit line at a lateral surface of a lower part of the vertical pillar, and forming a word line to be extended along a direction perpendicular to the bit line at a lateral surface of the vertical channel of the vertical pillar. The height of a lower end of the vertical channel may be lower than that of an upper end of the diffusion control layer.

### BRIEF DESCRIPTION OF THE DRAWINGS

FIGS. 1 and 2 show problems encountered in a semiconductor device, including a conventional vertical pillar structure.

FIGS. 3 to 7 sequentially show a method for forming a semiconductor device according to an embodiment of the present invention.

### DESCRIPTION OF EMBODIMENTS

Reference will now be made in detail to an embodiment of the present invention, examples of which are illustrated in the accompanying drawings. Wherever possible, the same reference numerals will be used throughout the drawings to refer to the same or like parts. A semiconductor device and a method for forming the same according to an embodiment of the present invention will hereinafter be described with reference to the appended drawings.

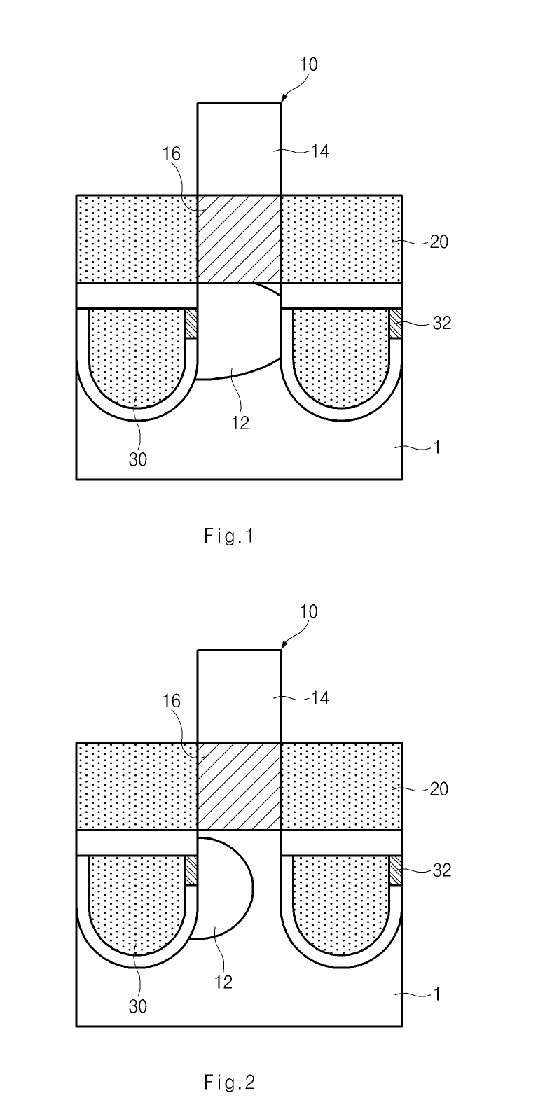

FIGS. 1 and 2 show problems encountered in a conventional vertical pillar structure. Referring to FIGS. 1 and 2, the semiconductor device includes a vertical pillar 10 vertically extending from a semiconductor substrate 1. Sequentially, from the bottom of the vertical pillar, the semiconductor device includes a first junction region 12, a channel region 16, and a second junction region 14. The first junction region 12 and the second junction region 14 operate as a source and a drain of the transistor, respectively. In the above-mentioned semiconductor device, a channel is formed in the channel region 16 between the first junction region 12 and the second junction region 14, and is formed in a vertical direction such that the channel serves as a vertical channel.

A gate 20 is formed at first and second sidewalls of the vertical pillar 10. The gate 20 may be extended along sidewalls of the vertical pillar 10 to a third or a fourth sidewall of the vertical pillar 10, and may be configured to enclose the vertical pillar 10.

The bit line 30 is extended to cross the gate 20, and is coupled to the first junction region 12 of the vertical pillar 10. For example, as shown in FIGS. 1 and 2, the bit line 30 located at the left side is coupled to the first junction region 12 of the vertical pillar 10. In FIGS. 1 and 2, the bit line 30 located at the right side is coupled to another first junction region (not shown) of the vertical pillar located at the right side of the bit line 30. The bit line 30 may be a buried bit line formed in the semiconductor substrate 1.

The bit line 30 is coupled to the first junction region 12. The bit line 30 and the first junction region 12 are coupled to each other through a sidewall contact 32. The first junction region 12 may be formed by ion implantation through the sidewall contact 32, or by an out diffusion method in which a thermal processing is performed onto a sacrificial layer (not shown) over the bit line 30 so that ions in the sacrificial layer are diffused into the vertical pillar 10 through the sidewall contact 32.

In the process for forming the first junction region 12, if ions are excessively implanted or diffused, as shown in FIG. 1, the first junction region 12 is formed extending up to the opposite surface (i.e., the right surface of FIG. 1) of the vertical pillar 10 to separate the channel region 16, formed over the first junction region 12, from the semiconductor substrate 1. The vertical pillar 10 is separated from the semiconductor substrate 1 such that the floating body effect occurs, resulting in a variety of problems affecting the performance of a transistor.

In contrast, in the process for forming the first junction region 12, as shown in FIG. 2, when the first junction region 12 is shallow, the channel region 16, between the first junction region 12 and the bit line 30, may be insufficiently formed. That is, the upper end of the first junction region 12 is formed to be lower than the lower end of the gate 20, thus increasing channel resistance a threshold voltage (Vt), and the driving current.

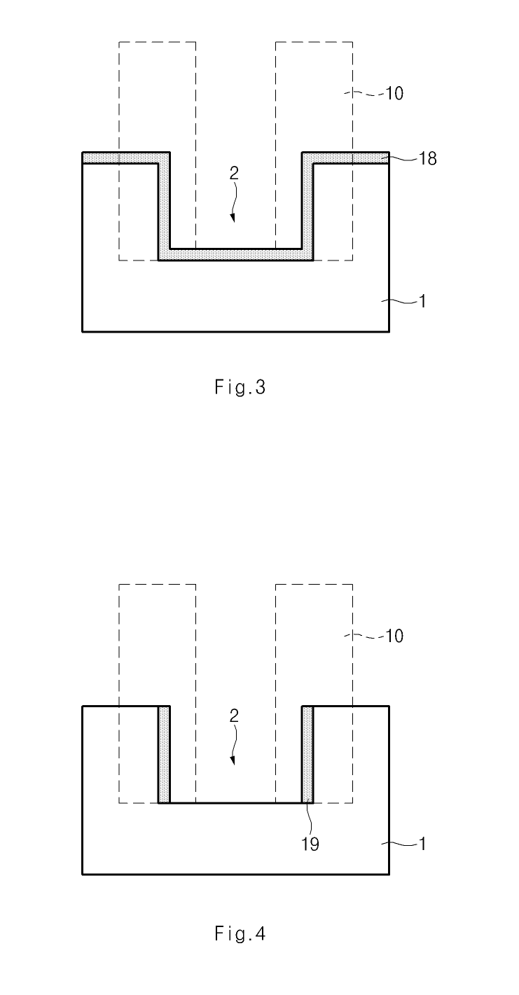

FIGS. 3 to 7 sequentially show a method for forming a semiconductor device according to an embodiment of the present invention. FIGS. 3 to 7 show a method for forming the semiconductor device to solve the above-mentioned problems. In FIGS. 3 to 7, the same elements as those of FIGS. 1 and 2 are denoted by the same reference numerals, and a duplicated description thereof will herein be omitted for convenience of description and better understanding of the present invention. Wherever possible, the same reference numerals will be used throughout the drawings to refer to the same or like parts.

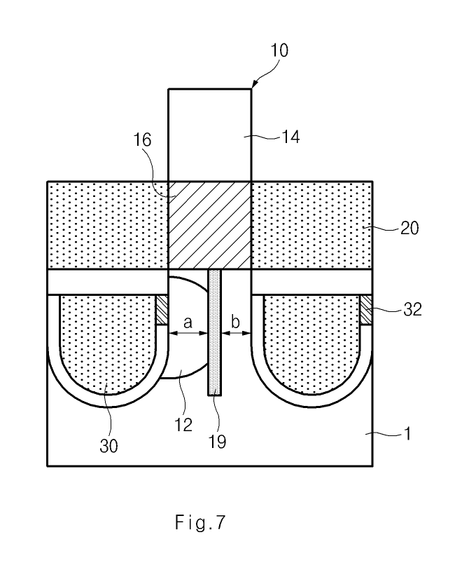

Referring to FIG. 7, the first junction region 12, the channel region 16, and the second junction region 14 are formed in the vertical pillar 10. The gate formed over the channel region and the bit line 30 formed over the first junction region 12 are identical to those of FIGS. 1 and 2.

Unlike the embodiment of FIGS. 1 and 2, a semiconductor device according to an embodiment of the present invention additionally forms a diffusion control layer (or also referred to as “diffusion control layer”) 19 in the vertical pillar 10, including the first junction region 12. The diffusion control layer 19 may include an oxide film or a nitride film. Preferably, the upper end of the diffusion control layer 19 may extend to the same or higher level than the lower end of the channel region 16. Preferably, the diffusion control layer 19 may be configured in the form of a flat square plate extending parallel to the bit line 30.

Although the diffusion control layer 19 may be located at the center of the vertical pillar 10, its position is not limited thereto. It may be located at any position so long as the channel region 16 can maintain a coupling with the substrate 1, but it is preferably located close to the center of the vertical pillar 10. Preferably, as shown in FIG. 7, the distance (a) between the diffusion control layer 19 and a first sidewall of the vertical pillar 10, where the sidewall contact 32 is formed, may be set to be 0.5 to 2 times the distance (b) between the diffusion control layer 19 and a second sidewall opposite to the first sidewall of the vertical pillar 10 where there is no sidewall contact 32. As shown in FIG. 7, if the diffusion control layer 19 is formed shallow and is located too close to the first sidewall, the first junction region 12 and the channel region 16 may not be sufficiently coupled to each other. However, if the diffusion control layer 19 is formed deeply such that it reaches the second sidewall, the floating body effect may result.

As described above, the diffusion control layer 19 is configured to control horizontal diffusion of ions (or dopants) during the ion implantation or ion diffusion process for forming the first junction region 12. The diffusion control layer 19 adjusts a diffusion depth of the first junction region 12. For this purpose, it is preferable that the diffusion control layer 19 be configured in the form of a plate to separate the first sidewall and the second sidewall of the pillar 10, as shown in FIG. 7, such that excessive diffusion through the sidewall contact 32 can be prevented. In an embodiment, the diffusion control layer 19 is configured to prevent vertical diffusion of ions along the sidewall surfaces of the pillar 10, and thus ions are diffused to a location close to the channel region 16.

As a result, the diffusion control layer 19 can prevent the floating body effect, which might have otherwise been caused by an ion implantation process or an ion diffusion process employed to form the first junction region 12. The floating body effect indicates that the vertical pillar 10 and the semiconductor substrate 1 are separated from each other by the first junction region 12 due to excessive ion implantation or diffusion. The diffusion control layer 19 may also prevent the first junction region 12 from being deeply formed toward the second sidewall of the pillar 10, while ensuring that the first junction region 12 is sufficiently diffused along the sidewall surface of the pillar 10 so as to be coupled to a lower part of the channel region 16.

A method for forming the above-mentioned semiconductor device according to embodiments of the present invention will hereinafter be described with reference to FIGS. 3 to 7.

Referring to FIG. 3, the semiconductor substrate 1 is partially etched so that a trench 2, having a predetermined depth, is formed. Preferably, the etching depth of the trench 2 defines the length of the first junction region 12. Thereafter, the diffusion control layer 18 is deposited over the entire surface of the semiconductor substrate 1, including the trench 2. The diffusion control layer 18 is an insulation film, and may include an oxide film or a nitride film. Preferably, the diffusion control layer 18 may be deposited by a Chemical Vapor Deposition (CVD) or an Atomic Layer Deposition (ALD) process in such a manner that the diffusion control layer 18 can be formed to a sufficient thickness at sidewalls of the trench 2. The dotted region of FIG. 3 indicates a region reserved for the vertical pillar 10, which will be formed later. Preferably, the diffusion control layer 18 is located in the center of the vertical pillar 10.

Referring to FIG. 4, the diffusion control layer 18 is etched back, and the remaining diffusion control layer 18 that is deposited over the surface of the semiconductor substrate 1 at the surface of the trench 2, other than the diffusion control layer 18 formed at sidewalls of the trench 2, is removed. As a result, the diffusion control layer pattern 19 remains only at sidewalls of the trench 2.

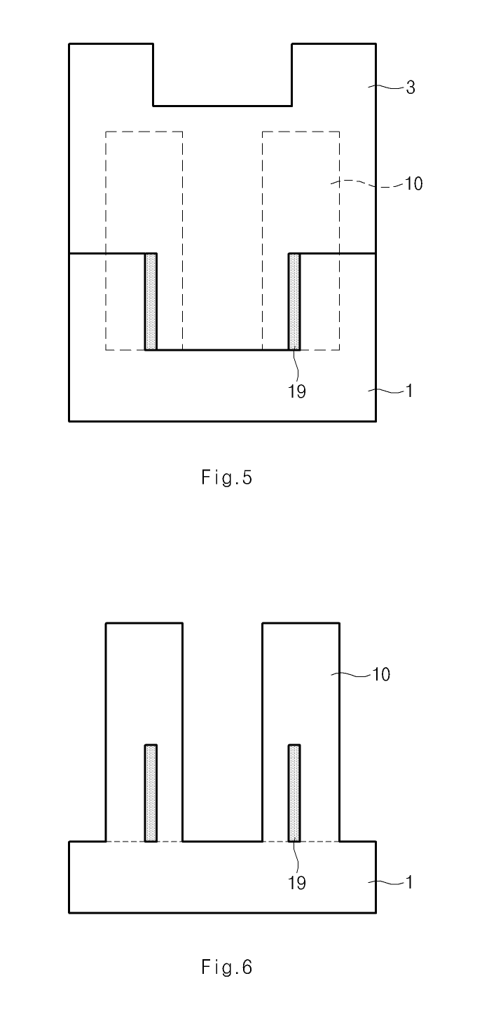

Referring to FIG. 5, the selective epitaxial growth (SEG) process that uses the semiconductor substrate 1, including the diffusion control layer pattern 19, as a seed, is performed such that a silicon layer 3 having a sufficient height that is capable of surrounding and covering the entire area of the diffusion control layer pattern 19 can be formed. The silicon layer 3 is etched in a subsequent process to form the vertical pillar 10. Preferably, the silicon layer 3 may be formed to extend to a level that corresponds to the sum of the channel length and the length of the second junction region 14 (See FIG. 7), measured from the top surface of the diffusion control layer pattern 19. Thereafter, an upper part of the silicon layer 3 is planarized through a Chemical Mechanical Polishing (CMP) process.

Referring to FIG. 6, an etch mask (not shown) is formed over the planarized silicon layer 3. The silicon layer 3 and the semiconductor substrate 1 are etched using the etch mask, so that the vertical pillar 10 is formed. As a result, the diffusion control layer pattern 19 may be formed at the center of a lower part of the vertical pillar 10.

Referring to FIG. 7, the bit line 30 is formed between the vertical pillars 10, and is formed at sidewalls of a lower part of the vertical pillars 10 in which the first junction region 12 is to be formed. The bit line 30 may include a conductive layer, such as polysilicon or tungsten, or may be formed by implanting ions into the semiconductor substrate 1. In this case, the sidewall contact 32 is formed at one sidewall where the bit line 30 contacts the vertical pillar 10. In accordance with the process for forming the sidewall contact 32, after only some parts of the bit line 30 are formed, sidewalls of the exposed vertical pillar 10 are etched so that the sidewall contact 32 can be formed.

In addition, ion implantation or ion diffusion is carried out through the bit line 30 and the sidewall contact 32, so that the first junction region 12 is formed. In other words, the ion implantation is performed through the sidewall contact 32 under the condition that only a lower part of the bit line 30 are formed and an upper part of the bit line 30 are not formed, such that the first junction region 12 can be formed. If the bit line 30 is formed of doped polysilicon, etc., ions are diffused to the vertical pillar 10 through the sidewall contact 32, so that the first junction region 12 can be formed.

Thereafter, through an additional ion implantation process, the second junction region 14 can be formed, and the gate 20 is formed over sidewalls of the vertical pillar 10 between the first and the second junction regions 12 and 14. Since the gate 20 is formed to cross the bit line 30, it is preferable that the gate 20 be formed along the right and left directions of FIG. 7. In addition, as described above, the gate 20 may be extended in a straight line along both sidewalls of the vertical pillar 10, or the gate 20 may also be formed of a surrounding gate that is extended to the straight line direction while simultaneously enclosing each vertical pillar 10.

As is apparent from the above description, a semiconductor device or a method for forming the same according to the present invention prevents separation between the channel region and the semiconductor substrate, preventing the floating body effect and guaranteeing a sufficient overlap between the gate and the junction region.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a vertical pillar including a vertical channel;
a diffusion control layer disposed in the vertical pillar; and
a first junction region formed adjacent to the diffusion control layer in the vertical pillar.

2. The semiconductor device according to claim 1, wherein the diffusion control layer includes an oxide film or a nitride film, or both.

3. The semiconductor device according to claim 1, wherein the diffusion control layer has a form of a plate.

4. The semiconductor device according to claim 1, wherein an upper end of the diffusion control layer is at substantially the same level as or a higher level than a lower end of the vertical channel.

5. The semiconductor device according to claim 1, wherein a distance (a) between the diffusion control layer and a first sidewall of the vertical pillar is 0.5 to 2 times a distance (b) between the diffusion control layer and a second sidewall of the vertical pillar, and
wherein the first junction region is formed along the first sidewall of the vertical pillar.

6. The semiconductor device according to claim 1, further comprising a second junction region formed over the vertical channel in the vertical pillar.

7. The semiconductor device according to claim 1, further comprising a bit line formed over a lower part of the first sidewall of the vertical pillar to be coupled to the first junction region.

8. The semiconductor device according to claim 7, wherein the junction region is located between a sidewall of the bit line of the vertical pillar and the diffusion control layer.

9. The semiconductor device according to claim 7, wherein the diffusion control layer is formed in parallel to the bit line, and is extended from a sidewall of a first side of the vertical pillar to a sidewall of a second side of the vertical pillar.

10. The semiconductor device according to claim 7, further comprising:
a sidewall contact between the first junction region and the bit line.

11. The semiconductor device according to claim 7, further comprising:
a word line formed over the vertical channel and arranged perpendicular to the bit line.

12. A method for forming a semiconductor device comprising:
forming a diffusion control layer over a semiconductor substrate, the diffusion control layer being configured to control diffusion of dopants;
forming a vertical pillar around the diffusion control layer; and
forming a first junction region adjacent to the diffusion control layer in the vertical pillar.

13. The method according to claim 12, wherein the forming of the diffusion control layer includes:
forming a trench by etching the semiconductor substrate; and
forming an insulation film at sidewalls of the trench.

14. The method according to claim 13, wherein the insulation film includes an oxide film or a nitride film, or both.

15. The method according to claim 12, wherein the forming of the vertical pillar includes:
forming a silicon layer over the semiconductor substrate over which the diffusion control layer is formed, and surrounding the diffusion control layer; and
etching the silicon layer to form the vertical pillar.

16. The method according to claim 15, wherein the forming of the silicon layer includes:
performing a selective epitaxial growth (SEG) on the semiconductor substrate over which the diffusion control layer is formed; and
planarizing an upper part of the SEG-processed silicon layer.

17. The method according to claim 12, wherein the forming of the first junction region includes:
forming a sidewall contact at a sidewall of the vertical pillar; and
providing ions into the first junction region through the sidewall contact.

18. The method according to claim 12, wherein a distance (a) between the diffusion control layer and a first sidewall of the vertical pillar is 0.5 to 2 times a distance (b) between the diffusion control layer and a second sidewall of the vertical pillar, and
wherein the first junction region is formed along the first sidewall of the vertical pillar.

19. The method according to claim 12, further comprising:
after forming the first junction region to be close to the diffusion control layer,
forming a second junction region over the vertical channel in the vertical pillar.

20. The method according to claim 12, the method further comprising:
forming a bit line over a lower part of the first sidewall of the vertical pillar; and
forming a word line arranged perpendicular to the bit line and coupled to the bit line through the vertical channel of the vertical pillar.

21. The method according to claim 20, wherein the lower end of the vertical channel is located lower than that of the upper end of the diffusion control layer.

22. A semiconductor device comprising:
a vertical pillar formed over a substrate, the vertical pillar including an upper pillar and a lower pillar vertically extending to each other;
a diffusion control layer formed in the lower pillar, the diffusion control layer dividing the lower pillar into a first pillar body and a second pillar body;
a vertical channel formed along a sidewall of the upper pillar; and
a first junction region formed in the first pillar body and coupled to the vertical channel,
wherein the upper pillar is coupled to the second pillar body of the lower pillar.

23. The semiconductor device of claim 22, wherein the diffusion control layer is an insulating layer.

24. The semiconductor device of claim 22, wherein the diffusion control layer is configured to define a depth of the first junction region.

25. The semiconductor device of claim 22, the device further comprising:
a second junction region formed over the upper pillar,
wherein the first junction region is coupled to a first end of the vertical channel and the second junction region is coupled to a second end of the vertical channel.
